(19) United States
(12) Patent Application Publication
(10) Pub. No.: US 2026/0324353 A1
(43) Pub. Date: Oct. 15, 2026

(54) ELECTROSTATIC CHUCK

(71) Applicant: TOTO LTD., Fukuoka (JP)

(72) Inventors: Takashi TAMADA, Fukuoka (JP); Jun SHIRAISHI, Fukuoka (JP); Hitoshi SASAKI, Fukuoka (JP)

(73) Assignee: TOTO LTD., Fukuoka (JP)

(21) Appl. No.: 19/467,126

(22) Filed: Feb. 2, 2026

(30) Foreign Application Priority Data
Mar. 17, 2025 (JP) 2025-042648

(51) Int. Cl. H10P 72/72; H02N 13/00

(52) U.S. Cl. CPC H10P 72/722; H02N 13/00

(57) ABSTRACT

An electrostatic chuck 10 includes a dielectric substrate 100, a base plate 200 supporting the dielectric substrate 100, and a joining layer 300 joining the dielectric substrate 100 with the base plate 200. The dielectric substrate 100 is formed of a material containing alumina as a principal component. The base plate 200 is formed of a material containing aluminum nitride as a principal component.

### CROSS-REFERENCE TO RELATED APPLICATION

This application is based upon and claims the benefit of priority from Japanese Patent Application No. 2025-042648 filed on Mar. 17, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate inside which an attraction electrode is provided and a base plate which supports the dielectric substrate, and these are joined to each other. When a voltage is applied to the attraction electrode, an electrostatic force is generated, and the wafer placed on the dielectric substrate is attracted and held.

As disclosed in International Publication No. WO 2022/255118, the dielectric substrate is typically formed of a ceramics material such as alumina, for example. On the other hand, the base plate is typically formed of a metallic material such as aluminum, for example, in order to enhance its cooling performance.

### SUMMARY

A metallic material is a material having a larger coefficient of linear expansion as compared with a ceramics material. Due to this, when a temperature of the electrostatic chuck increases or decreases in the semiconductor manufacturing apparatus, there is a possibility that may peeling (delamination)occur between the dielectric substrate and the base plate due to the difference in coefficients of linear expansion. Particularly in recent semiconductor manufacturing apparatuses, in order to meet requirements such as multilayering, etching processing has come to be performed in an extremely low-temperature environment. For this reason, it is considered that the above-described peeling problem will become more likely to occur in the future.

The present invention has been made in view of such a problem and aims at providing an electrostatic chuck that can suppress peeling between the dielectric substrate and the base plate.

To solve the above-described problem, the electrostatic chuck according to the present invention includes: a dielectric substrate including a placement surface on which an object to be attracted is placed; a base plate supporting the dielectric substrate; and a joining layer joining the dielectric substrate with the base plate. The dielectric substrate is formed of a material containing alumina as a principal component. The base plate is formed of a material containing aluminum nitride as a principal component.

Aluminum nitride is a material having a thermal conductivity substantially equal to that of aluminum, but its coefficient of linear expansion is substantially equal to that of alumina. By forming the base plate using aluminum nitride in place of a metallic material as in the related art, it is possible to suppress peeling between the dielectric substrate and the base plate without sacrificing its cooling performance.

According to the present invention, it is possible to provide an electrostatic chuck capable of suppressing peeling between the dielectric substrate and the base plate.

### BRIEF DESCRIPTION OF THE DRAWINGS

FIG. 1 is a cross-sectional view schematically illustrating a configuration of an electrostatic chuck according to the present embodiment;

FIG. 2 is a cross-sectional view schematically illustrating an inner part of a joining layer of the electrostatic chuck according to the present embodiment; and

FIG. 3 is a diagram illustrating respective physical properties of alumina, aluminum, and aluminum nitride.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

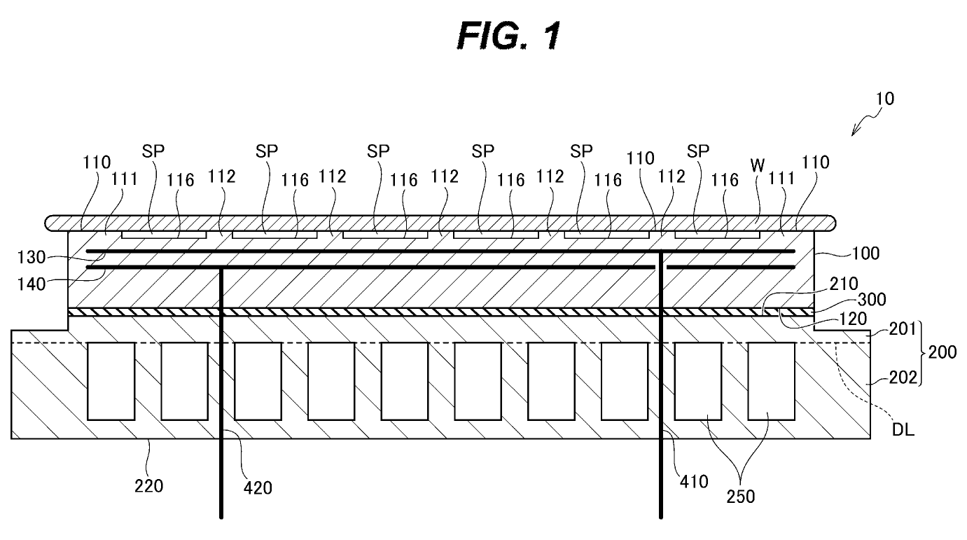

FIG. 1 is a cross-sectional view schematically illustrating a configuration of the electrostatic chuck 10 in a state in which the wafer W is attracted and held. The electrostatic chuck 10 includes a dielectric substrate 100, a base plate 200, and a joining layer 300.

The dielectric substrate 100 is a substantially disk-shaped member formed of a ceramic sintered body. The dielectric substrate 100 is formed of, for example, a material containing highly pure alumina (Al₂O₃) as a principal component. A ceramics purity or type, an additive, or the like in the dielectric substrate 100 may be appropriately set by taking into account plasma resistance or the like needed for the dielectric substrate 100 in the semiconductor manufacturing apparatus.

In the present specification, the term "principal component" refers to a compound that is confirmed to be contained in a target object in a relatively larger amount than any other compound contained therein, when quantitative or semi-quantitative analysis is performed on the target object such as the dielectric substrate 100 by X-ray Diffraction (XRD). A ratio occupied by alumina as the principal component is larger than 50% in the dielectric substrate 100 of the present embodiment. The ratio is more preferably equal to or larger than 90%, and even more preferably equal to or larger than 95%.

When alumina is used as a material of the dielectric substrate 100 as in the present embodiment, it is preferable that a purity of alumina used as a raw material in the dielectric substrate 100 is set to be equal to or larger than 99.5%, or equal to or larger than 99.9%. By increasing the purity of alumina to such a level, it is possible to sufficiently ensure durability of the dielectric substrate 100 against plasma. A volume resistivity of the dielectric substrate 100 is preferably set to be equal to or larger (higher) than 1×10¹⁴ Ω⋅cm in a case of a Coulomb-force type electrostatic chuck, and is preferably set to fall within a range of 1×10⁹ to 1×10¹² Ω⋅cm in a case of a Johnsen-Rahbek-force type electrostatic chuck.

A surface 110 on an upper side in FIG. 1 in the dielectric substrate 100 serves as a "placement surface" on which the wafer W is placed. A surface 120 on a lower side in FIG. 1 in the dielectric substrate 100 serves as a "surface to be joined" which is joined to the base plate 200 via the joining layer 300. A perspective in a case where the electrostatic chuck 10 is viewed from the surface 110 side along a direction perpendicular to the surface 110 will also be hereinafter expressed as "top view".

An attraction electrode 130 is embedded inside the dielectric substrate 100. The attraction electrode 130 is a thin planar(plate-like) layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line 410, an electrostatic force is generated between the surface 110 and the wafer W, and according to this, the wafer W is attracted and held. The single attraction electrode 130 may be provided as so-called a "monopolar" electrode as in the present embodiment, but may also include two attraction electrodes as so-called "bipolar" electrodes. The attraction electrode 130 corresponds to a "conductor layer" provided inside the dielectric substrate 100.

In FIG. 1, the feed line 410 is entirely illustrated in a simplified manner. A portion of the feed line 410 inside the dielectric substrate 100 is configured as an elongated via (hole) filled with a conductor, for example, and a feed terminal is provided at a lower end thereof. A portion of the feed line 410 penetrating the base plate 200 is a rod-shaped metal whose one end is connected to the above-described feed terminal. A through hole which is not illustrated in the drawing for inserting the metal is formed in the base plate 200. As a configuration of the feed line 410 for applying a voltage to the attraction electrode 130, various well-known configurations can be adopted in addition to the above-described configuration.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When a high-frequency alternating-current voltage is applied between these counter electrodes, plasma is generated on the upper side of the wafer W and used for processing such as film deposition and etching on the wafer W.

Similarly to the attraction electrode 130, the RF electrode 140 is a thin planar layer made of a metallic material such as, for example, tungsten. As a material of the RF electrode 140, molybdenum, platinum, palladium, and the like may be used in addition to tungsten. The RF electrode 140 is embedded at a position closer to the surface 120 side than the attraction electrode 130. Similarly to the attraction electrode 130, the RF electrode 140 is arranged so as to be parallel to the surface 110. The RF electrode 140 is a single electrode which is substantially circular in top view. In top view, a center of the RF electrode 140 matches a center of the dielectric substrate 100. The RF electrode 140 corresponds to another "conductor layer" provided inside the dielectric substrate 100. In the present embodiment, a plurality of conductor layers including the attraction electrode 130 and the RF electrode 140 are provided at height positions different from each other.

A feed line 420 is connected to the RF electrode 140. The feed line 420 constitutes an electric circuit for applying a voltage to the RF electrode 140 from the outside. In FIG. 1, the feed line 420 is entirely illustrated in a simplified manner. A portion of the feed line 420 inside the dielectric substrate 100 is configured as an elongated via (hole) filled with a conductor, for example, and a feed terminal is provided at a lower end thereof. A portion of the feed line 420 penetrating the base plate 200 is a rod-shaped metal whose one end is connected to the above-described feed terminal. A through hole which is not illustrated in the drawing for inserting the metal is formed in the base plate 200. As a configuration of the feed line 420 for applying a voltage to the RF electrode 140, various well-known configurations can be adopted in addition to the above-described configuration.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 serves as a part of the surface 110 and abuts against the wafer W. The distal end of the seal ring 111 can be referred to as a part on an outermost circumferential side on the surface 110 which serves as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A distal end of each of the dots 112 becomes a part of the surface 110 and abuts against the wafer W. By providing the plurality of thus configured dots 112, warping of the wafer W is reduced.

In order that the helium gas supplied from a gas hole which is not illustrated in the drawing be rapidly supplied to each part of the space SP, a groove may be formed in the bottom 116. It is preferable that the groove be formed to pass through a position of the gas hole.

Additionally, after forming a plurality of gas holes in the dielectric substrate 100, a distribution flow path for distributing the helium gas to the respective gas holes may be formed inside the electrostatic chuck 10. The distribution flow path may be formed as a groove on the surface 120 of the dielectric substrate 100, may be formed in the joining layer 300 described later, may be formed as a groove on a surface 210 of the base plate 200, which will be described next, or may be formed inside the base plate 200.

The base plate 200 is a substantially disk-shaped member which supports the dielectric substrate 100. The base plate 200 is formed of a material containing aluminum nitride (AlN) as a principal component. The base plate 200 is joined to the surface 120 of the dielectric substrate 100 via the joining layer 300 described later. The surface 210 on the upper side in FIG. 1 in the base plate 200 serves as a "surface to be joined" which is joined to the dielectric substrate 100.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

The base plate 200 is configured by combining a first member 201 and a second member 202. The first member 201 and the second member 202 are joined to each other by diffusion joining, for example. In FIG. 1, a joining interface between the first member 201 and the second member 202 is indicated by a dotted line DL. The base plate 200 may be configured by joining three or more members to each other.

The coolant flow path 250 is a groove that has been formed in advance, before both members are joined to each other, along a front surface of the second member 202 which abuts against the first member 201 (a surface on the upper side in FIG. 1). In this manner, by forming the groove in the front surface of the second member 202 in advance and joining the first member 201 so as to cover the front surface, the coolant flow path 250 along the groove can be easily formed inside the base plate 200. The distribution flow path for gas described above may also be formed inside the base plate 200 by a similar method.

The joining layer 300 is a layer provided between the dielectric substrate 100 and the base plate 200 to join those components. As the joining layer 300, an insulating material is preferably used. As the insulating material, an inorganic material such as ceramic or an organic material such as a resin can be used, for example. As the joining layer 300, it is possible to use one obtained by curing an adhesive containing any of the above-described materials. As the adhesive, various well-known materials can be used. For example, an inorganic adhesive such as Aron Ceramic manufactured by Toagosei Co., Ltd., SUMICERAM-S manufactured by Asahi Chemical Co., Ltd., or Ceramabond manufactured by Aremco Products Inc. can be used. It is preferable to configure the joining layer 300 with an inorganic adhesive because plasma resistance and thermal conductivity of the joining layer 300 can be enhanced. Additionally, an organic adhesive or the like such as a silicone adhesive can be used, for example.

In the present embodiment, a silicone adhesive is used as the above-described adhesive. That is, the joining layer 300 of the present embodiment is formed of a material containing silicone resin. The resin contained in the joining layer 300 may be a resin other than silicone resin.

To reduce thermal resistance between the dielectric substrate 100 and the base plate 200, it is preferable that a thermal conductivity of the joining layer 300 be as high as possible. In the present embodiment, to enhance the thermal conductivity of the joining layer 300, a plurality of filling materials 320 are arranged in a distributed manner inside the joining layer 300. The filling material 320 is also referred to as a so-called "filler" or the like.

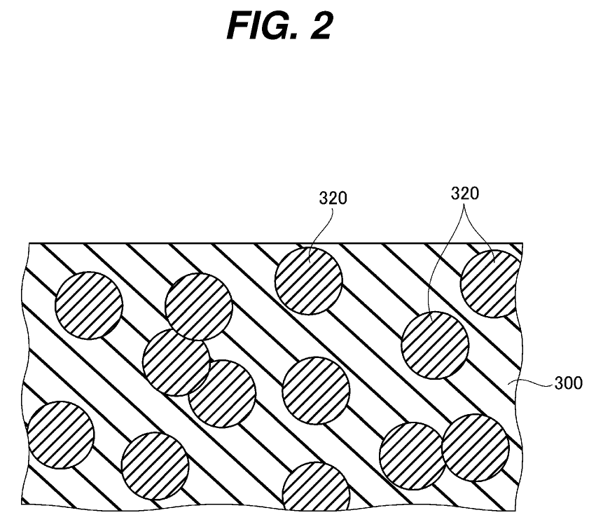

FIG. 2 is a cross-sectional view schematically illustrating a configuration of an inner part of the joining layer 300. The filling materials 320 are, for example, particulate members containing alumina as a principal component, and have been previously mixed in a predetermined amount (for example, 60 to 90% by weight) into the silicone adhesive before curing. A material of the filling material 320 may be a material other than alumina as long as the material has a higher thermal conductivity than that of the joining layer 300. For example, the filling material 320 may be formed of a material containing aluminum nitride (AlN), silicon carbide (SiC), silicon dioxide (SiO₂), or the like as a principal component.

A shape of each of the filling materials 320 is, for example, spherical, but may be a shape other than spherical. In any case, it is preferable that each of the filling materials 320 be sufficiently small as compared with an overall thickness of the joining layer 300. As a content of the filling materials 320 in the joining layer 300 is increased, the thermal conductivity of the joining layer 300 can be enhanced. The content of the filling materials 320 is appropriately adjusted in accordance with heat transfer performance required for the joining layer 300.

In an electrostatic chuck in the related art, a metallic material such as aluminum has been typically used as a material of the base plate 200, for example. The metallic material is a material having a relatively high thermal conductivity, so that the dielectric substrate 100 can be efficiently cooled by a coolant passing through the coolant flow path 250.

However, the metallic material is a material having a larger coefficient of linear expansion as compared with the ceramics material constituting the dielectric substrate 100. Due to this, when a temperature of the electrostatic chuck 10 increases or decreases in the semiconductor manufacturing apparatus, there is a possibility that peeling occurs between the dielectric substrate 100 and the base plate 200 due to a difference in coefficients of linear expansion. Particularly in recent semiconductor manufacturing apparatuses, in order to meet requirements such as multilayering, etching processing has come to be performed in an extremely low-temperature environment. For this reason, it is considered that the above-described peeling problem will become more likely to occur in the future.

Thus, in the electrostatic chuck 10 according to the present embodiment, as described above, a material containing aluminum nitride (AlN) as a principal component is used as the material of the base plate 200 instead of the metallic material.

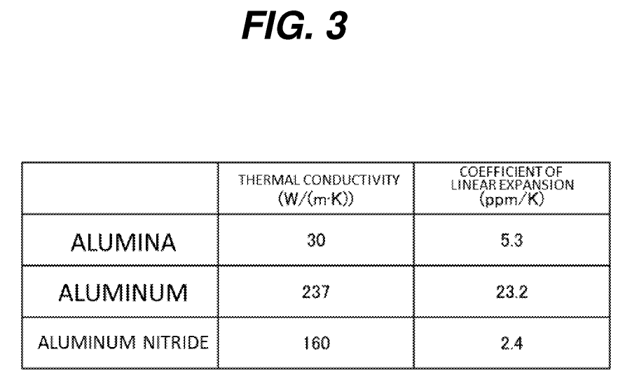

FIG. 3 illustrates respective physical properties (a thermal conductivity and a coefficient of linear expansion) of alumina, aluminum, and aluminum nitride. As illustrated in FIG. 3, a thermal conductivity of aluminum nitride is 160 W/(m⋅K), which is substantially equal to a thermal conductivity of aluminum (237 W/(m⋅K)). A coefficient of linear expansion of aluminum nitride is 2.4x10-⁶ /K, which is substantially equal to a coefficient of linear expansion of alumina (5.3x10⁻⁶ /K).

As described above, aluminum nitride is a material having a thermal conductivity substantially equal to that of aluminum, but its coefficient of linear expansion is substantially equal to that of alumina. By using, as the material of the base plate 200, aluminum nitride as described above in place of the metallic material as in the related art, it is possible to suppress peeling between the dielectric substrate 100 and the base plate 200 without sacrificing cooling performance of the base plate 200.

By adopting aluminum nitride as the material of the base plate 200, a thermal expansion difference between the dielectric substrate 100 and the base plate 200 becomes significantly smaller as compared with the related art. Due to this, the joining layer 300 can be made thinner than in the related art, and a degree of freedom in selecting its material also becomes higher. For example, it is also possible to greatly increase an amount of the filling materials 320 arranged inside the joining layer 300 as compared with the related art. Additionally, as described above, an inorganic material or the like having relatively low flexibility can also be used as the joining layer 300.

To further reduce the thermal expansion difference between the dielectric substrate 100 and the base plate 200, it is also conceivable to form both the dielectric substrate 100 and the base plate 200 using a material containing aluminum nitride as a principal component. However, aluminum nitride is a material having larger manufacturing constraints than alumina, for example, in that atmospheric firing cannot be performed. Due to this, in arranging a conductor layer inside the dielectric substrate 100, it is difficult to adjust a height position and a shape thereof with accuracy comparable to that in the related art. Additionally, it is considered that accuracy required for the dielectric substrate 100 will become even higher in the future with advancement of semiconductor manufacturing technology. Accordingly, as the material of the dielectric substrate 100, it is preferable to use alumina as in the present embodiment.

As in the present embodiment, in a case where a ceramic material is used as the material of the base plate 200 instead of the metallic material, the base plate 200 cannot be used as one of a pair of RF electrodes (a lower electrode). Thus, as in the present embodiment, the RF electrode 140 needs to be provided inside the dielectric substrate 100. It is also conceivable to provide the RF electrode 140 inside the base plate 200 made of a ceramic material. However, in such a case, a distance between an upper electrode, which is the other one of the RF electrodes, and the RF electrode 140 becomes excessively large, and there is a concern that controllability of plasma may deteriorate. Due to this, from a viewpoint of plasma controllability, it is preferable to provide the RF electrode 140 inside the dielectric substrate 100.

That is, in a case of using a ceramic material as the material of the base plate 200 instead of the metallic material, it is necessary to provide a plurality of conductor layers including at least the attraction electrode 130 and the RF electrode 140 inside the dielectric substrate 100. Also in view of this point, as the material of the dielectric substrate 100, it is preferable to use alumina, which is excellent in sinterability, instead of aluminum nitride.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed;
a base plate supporting the dielectric substrate; and
a joining layer joining the dielectric substrate with the base plate, wherein
the dielectric substrate is formed of a material containing alumina as a principal component, and
the base plate is formed of a material containing aluminum nitride as a principal component.

2. The electrostatic chuck according to claim 1, wherein the joining layer is formed of an inorganic material.

3. The electrostatic chuck according to claim 1, wherein the joining layer is formed of a material containing a resin.

4. The electrostatic chuck according to claim 3, wherein a plurality of particulate filling materials are arranged inside the joining layer.

5. The electrostatic chuck according to claim 1, wherein the dielectric substrate contains highly pure alumina having a purity of 99.5% or more as a principal component.

6. The electrostatic chuck according to claim 1, wherein a conductor layer is provided inside the dielectric substrate.

7. The electrostatic chuck according to claim 6, wherein a plurality of the conductor layers are provided at height positions different from each other.
